(19) United States
(12) Patent Application Publication
(10) Pub. No.: US 2016/0118712 A1
(43) Pub. Date: Apr. 28, 2016

(54) HOUSING, ELECTRONIC DEVICE USING SAME, AND METHOD FOR MAKING SAME

(71) Applicants: SHENZHEN FUTAIHONG PRECISION INDUSTRY CO., LTD., Shenzhen (CN); FIH (HONG KONG) LIMITED, Kowloon (HK)

(72) Inventors: CHANG-HAI GU, Shenzhen (CN); XIAO-KAI LIU, Shenzhen (CN)

(21) Appl. No.: 14/712,166

(22) Filed: May 14, 2015

(30) Foreign Application Priority Data
Oct. 23, 2014 (CN) 201410569879.1

(51) Int. Cl. H01Q 1/24; B29B 11/04; H05K 5/04; B29C 45/14

(52) U.S. Cl. CPC H01Q 1/243; B29C 45/14639; B29B 11/04; H05K 5/04; B29K 2995/0007; B29L 2031/3481

(57) ABSTRACT

A housing includes a base, a metal strip assembly, and insulating layers. The base has a number of main portions separated by one or more openings formed therein. The metal strip assembly is positioned within the openings. The metal strip assembly is formed by a series of metal strips fixed together by adhering layers. The insulating layers is positioned between the metal strip assembly and the main portions.

### FIELD

The subject matter herein generally relates to a housing, an electronic device using the housing, and a method for making the housing.

### BACKGROUND

Metal housings are widely used for electronic devices.

### BRIEF DESCRIPTION OF THE FIGURES

Implementations of the present technology will now be described, by way of example only, with reference to the attached figures.

FIG. 1 is an isometric view of an electronic device, according to an exemplary embodiment.

FIG. 2 is a partial, isometric view of a housing of the electronic device shown in FIG. 1.

FIG. 3 is similar to FIG. 2, but shown from another angle.

FIG. 4 is an exploded, isometric view of the housing shown in FIG. 1.

FIG. 5 is a cross-sectional view of the housing along line V-V of FIG. 2.

FIG. 6 is an enlarged view of the housing of circled portion VI in FIG. 5.

FIG. 7 is an isometric view of metal strips during the process of making the housing of FIG. 2.

FIG. 8 is an isometric view of a metal strip assembly during the process of making the housing of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series and the like. The term “coupled” when utilized, means “either a direct electrical connection between the things that are connected, or an indirect connection through one or more passive or active intermediary devices, but not necessarily limited to”.

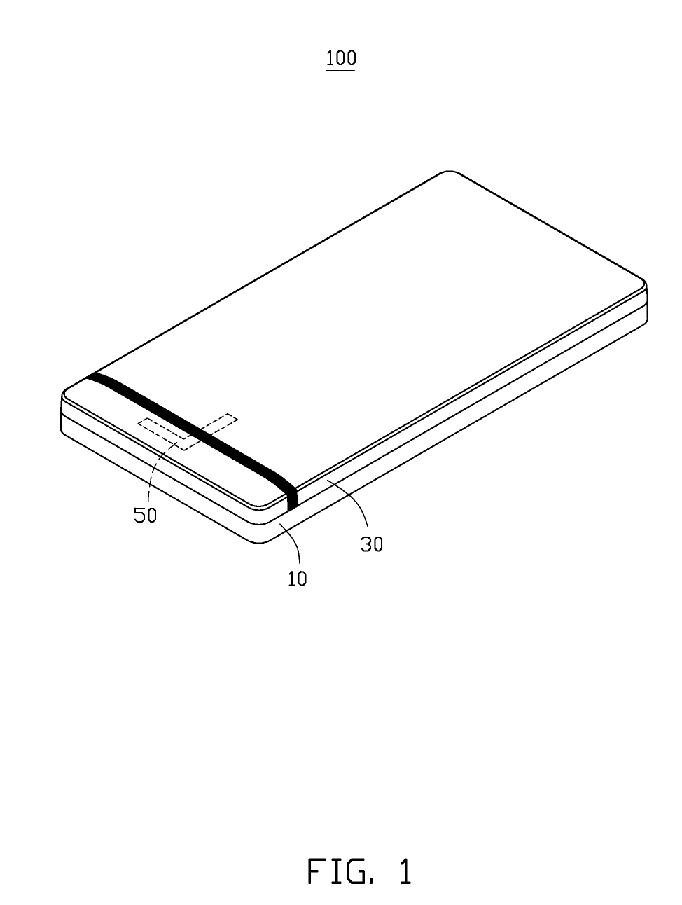

FIG. 1 illustrates an electronic device 100 according to an exemplary embodiment. The electronic device 100 can be, but not limited to, a mobile phone, a personal digital assistant or a panel computer. The electronic device 100 includes a main body 10, a housing 30 assembled to the main body 10, and an antenna 50 located inside the housing 30.

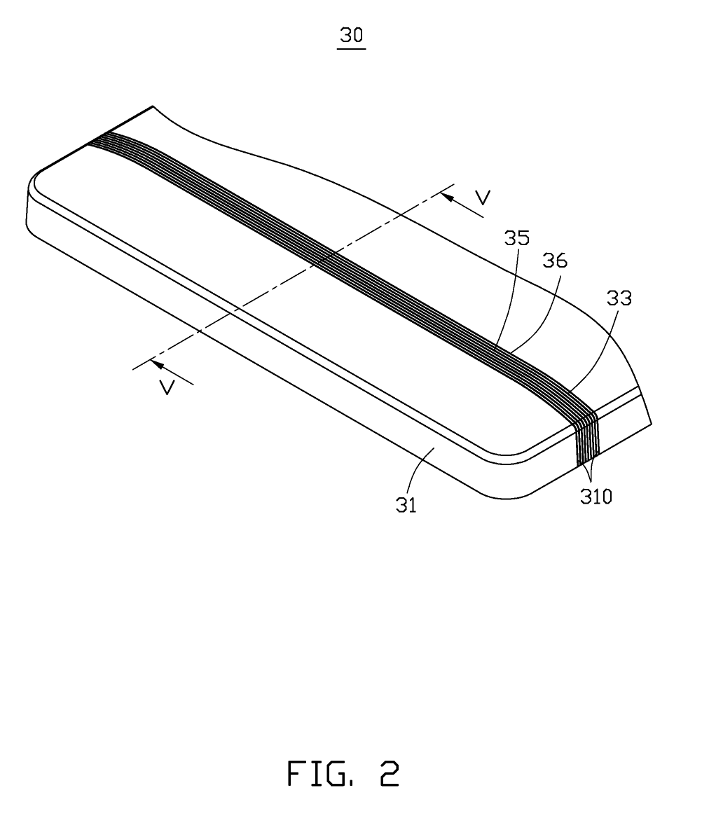

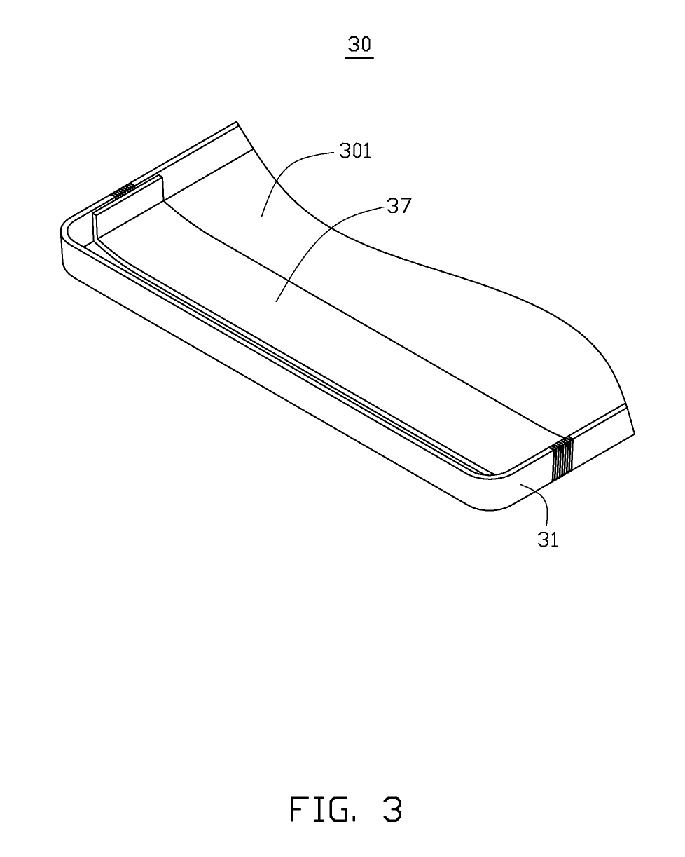

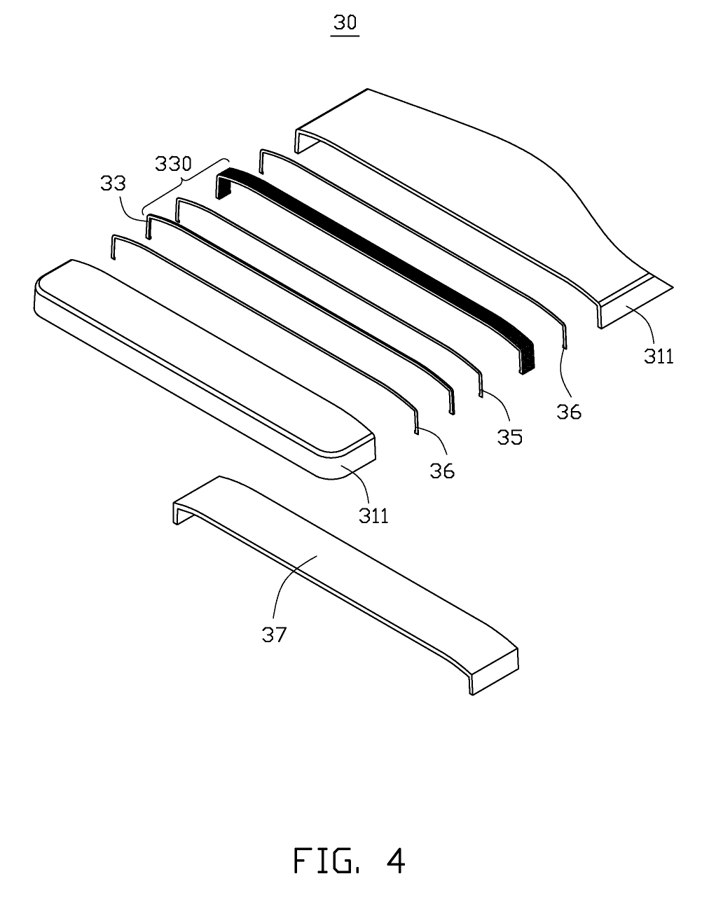

FIGS. 2-4 illustrate in one exemplary embodiment, the housing 30 can be a back cover of the electronic device 100. The housing 30 includes a base 31, a plurality of metal strips 33, a plurality of adhering layers 35, a plurality of insulating layers 36, and a combining layer 37 formed on the base 31. The base 31 further defines a receiving space 301 cooperating with main body 10 to receive internal elements of the electronic device 100, such as the antenna 50, battery (not shown) and so on.

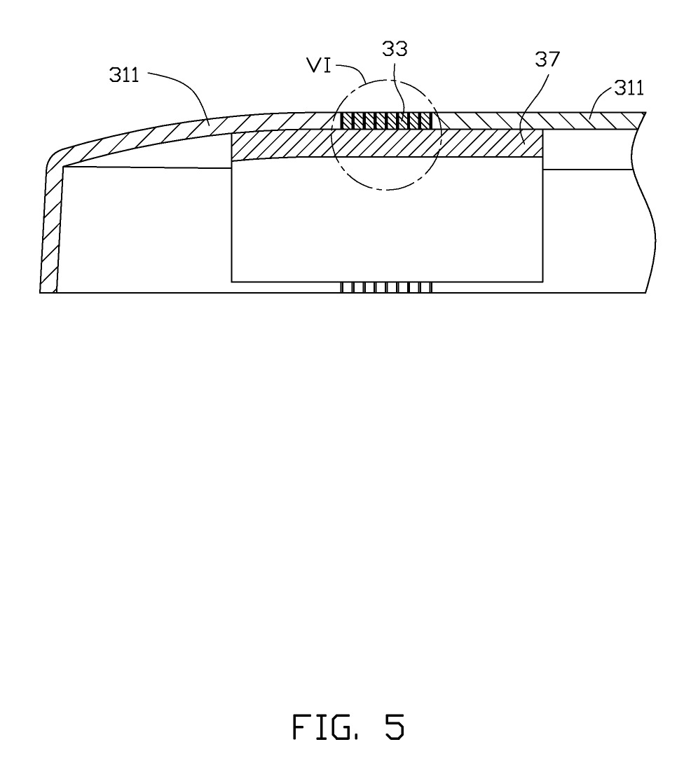

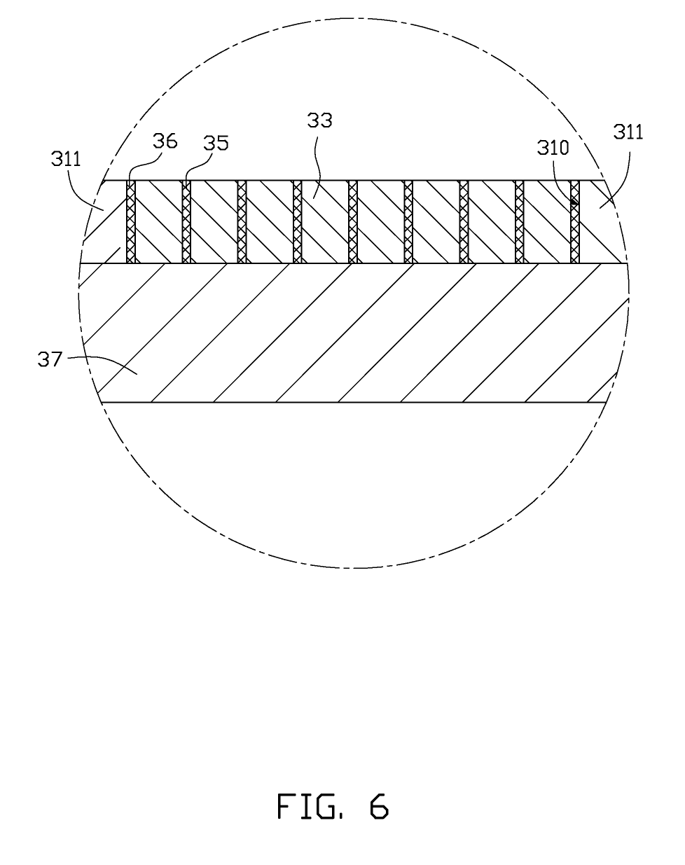

FIGS. 5-6 illustrate the base 31 is three-dimensional. In one exemplary embodiment, the base 31 has a substantially U-shaped cross-section. A plurality of openings 310 is defined in the base 31 corresponding with the antenna 50 received in the receiving space 301 and running through an outer surface and an inner surface of the base 31. The plurality of openings 310 divides the base 31 into at least two main portions 311. The at least two main portions 311 can be separated from each other or connected to each other through at least one portion of the base 31 adjacent to the openings 30. In one exemplary embodiment, the base 31 includes one opening 310 (shown in FIG. 6) dividing the base 31 into two separated main portions 311. The base 31 is made of metal. The metal can be selected from a group consisting of aluminum alloy, titanium alloy, magnesium alloy, and stainless steel.

Each metal strip 33 is also made of metal selected from a group consisting of aluminum alloy, titanium alloy, magnesium alloy, and stainless steel.

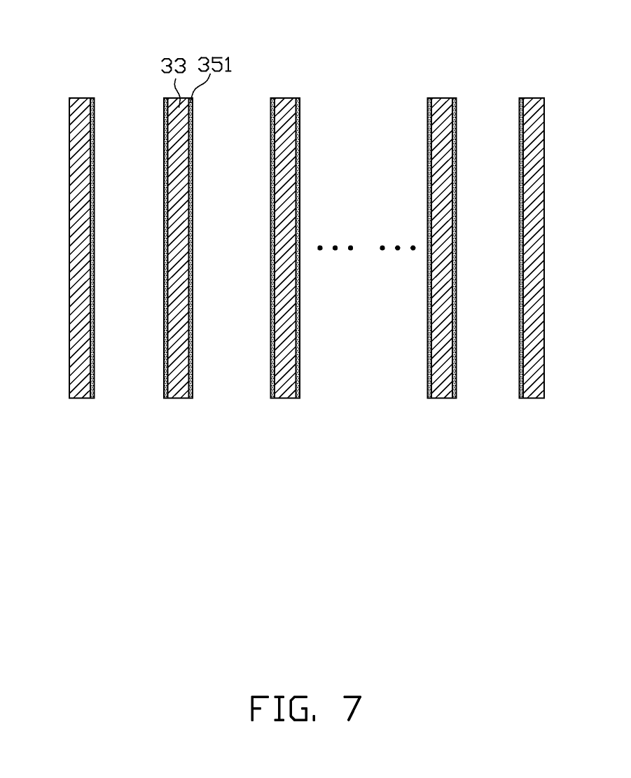

The metal strips 33, adhering layers 35, and the insulating layers 36 are received in the opening 310 and sandwiched between the two main portions 310. Each metal strip 33 alternates with one adhering layer 35. Each adhering layer 35 is positioned between each two adjacent metal strips 33, thereby adhering all the metal strips 33 together to form a metal strip assembly 330. The adhering layers 36 can be formed from plastic films 351 (shown FIG. 7) made of polycarbonate (PC), polyamide (PA), or polyethylene terephthalate (PET) through hot pressing. The insulating layers 36 are positioned between each main portion 311 and the metal strip 33 adjacent to the main portion 311, thereby physically but not electrically connecting the main portions 311 to the corresponding adjacent metal strips 33. The insulating layer 36 can be made of one or more resins selected from a group consisting of polyphenylene sulfide (PPS), polybutylene terephthalate (PBT), polyamide (PA), polyethylene terephthalate (PET), polytrimethylene terephthalate (PTT), polyetherimide (PEI), polyether ether ketone (PEEK), poly(ethylene-co-1,4-cyclohexylenedimethylene terephthalate) (PCT), and their modified materials, through injection molding.

In other embodiments, the insulating layers 36 also can be formed by the plastic films 351 made of polycarbonate (PC), polyamide (PA), or polyethylene terephthalate (PET), through hot pressing.

Each metal strip 33 has a thickness of about 0.1 mm to about 1.0 mm along a direction from an adjacent adhering layer 35 located at one side of the metal strip 33 to another adjacent adhering layer 35 located at an opposite side of the metal strip 33. Each adhering layer 35 has a thickness of about 20 μm to about 0.8 mm along a direction from a metal strip 33 located at one side of adhering layer 35 to another adjacent metal strip 33 located at an opposite side of the adhering layer 35, thereby creating a distance between each two adjacent metal strips 33 of about 20 μm to about 0.8 mm. In other embodiments, the thickness of each adhering layer 35 is about 0.15 mm. Each insulating layer 36 has a thickness of about 20 μm to about 0.8 mm along a direction from each main portion 311 to an adjacent metal strip 33, thereby creating a distance between each main portion 311 and the adjacent metal strip 33 of about 20 μm to about 0.8 mm. In the embodiment, the thickness of each insulating layer 36 is also about 0.15 mm. Therefore, requirements for reducing interference from the metal housing 30 with the antenna 30 can be satisfied.

The metal strips 33 are substantially U-shaped corresponding to the main portions 311. Each adhering layer 35 is adhered to adjacent metal strips 33. Each adhering layer 35 is also substantially U-shaped to engage with the shape of the metal strips 33.

The combining layer 37 is formed on the internal surface of the base 31 (i.e. a surface of the base 31 facing the main body 10). The combining layer 37 covers each metal strip 33, each adhering layer 35, each insulating layer 36, and entirely or partially covers an end portion of the main portion 311 connected to the insulating layers 36. As such, the main portions 311, the metal strips 33, the adhering layers 35, and the insulating layers 36 are bonded together through the combining layer 37. The combining layer 37 can further enhance a bonding strength among the main portions 311, the metal strips 33, the adhering layers 35, and the insulating layers 36, respectively. The combining layer 37 can be made of one or more resins selected from of a group consisting of polyphenylene sulfide (PPS), polybutylene terephthalate (PBT), polyamide (PA), polyethylene terephthalate (PET), polytrimethylene terephthalate (PTT), Polyetherimide (PEI), polyether ether ketone (PEEK), poly(ethylene-co-1,4-cyclohexylenedimethylene terephthalate) (PCT), and their modified materials.

When the housing 30 is assembled to the main body 10, the metal strip assembly 330 formed by the metal strips 33 and the adhering layers 35 aligns with the antenna 40. The base 31 can be coupled with the antenna and serves as an extra antenna of the electronic device 100. In addition, signals of the antenna 50 can pass through the adhering layers 35 and the insulating layers 36. Therefore, radiation efficiency of antenna 50 can be increased.

In another embodiment, the base 31 is not coupled with the antenna and does not serve as the extra antenna. The signals of the antenna 50 can pass through the adhering layers 35 and the insulating layers 36 to increase the radiation efficiency of antenna 50.

An exemplary method for making the housing 30 can include the following steps.

The base 31 having a three-dimensional shape is provided. The base 31 defines the plurality of openings 310 communicating through the base 31 and corresponding to the antenna 50. The openings 310 divide the base 31 into at least two main portions 311. The at least two main portions 311 can be separated from each other or connected to each other through at least one portion of the base 31 adjacent to the openings 30. In one exemplary embodiment, the base 31 includes one opening 310 dividing the base 31 into two separated main portions 310. The base 31 can be made by casting, punching, or computer numerical control machine. The base 31 is made of metal. The metal can be selected from a group consisting of aluminum alloy, titanium alloy, magnesium alloy, and stainless steel.

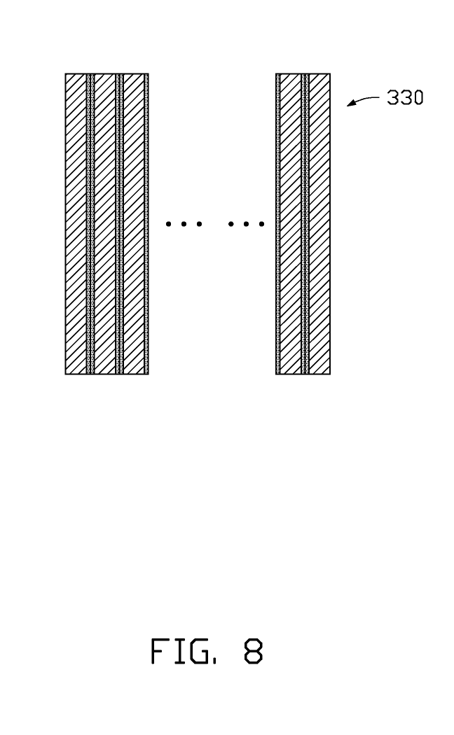

FIGS. 7 and 8 illustrate the plurality of metal strips 33 are provided. The plastic films 351 which can be melted upon heating are formed on each side surface of each metal strip 33 facing the adjacent metal strip 33. Each metal strip 33 is made of metal. The metal can be selected from a group consisting of aluminum alloy, titanium alloy, magnesium alloy, and stainless steel. The plastic film 351 can be made of polyamide (PA), polycarbonate (PC) or polyethylene terephthalate (PET).

The metal strips 33 formed with plastic films 351 are overlapping and connected together. Each two adjacent metal strips 33 are spaced by the plastic films 351. The overlapped metal strips 33 are heated to melt the plastic films 351. The plastic films 351 are then solidified, thereby adhering all the metal strips 33 together to form the metal strip assembly 330. In one exemplary embodiment, the metal strips 33 are placed in a mold (not shown) aligned with each other. The metal strips 33 are heated to melt the plastic films 351 positioned on each side surface of each metal strip 33 facing the adjacent metal strip 33, and then cooled to solidify the melted plastic films 351. Thus, the metal strips 33 are adhered together, and the plastic films 351 positioned between each two adjacent metal strips 33 form the plurality of adhering layers 35 sandwiched between each two adjacent metal strips 33. Each adhering layer 35 has a thickness of about 20 μm to about 0.8 mm along a direction from a metal strip 33 located at one side of adhering layer 35 to another adjacent metal strip 33 located at an opposite side of the adhering layer 35.

The metal strip assembly 330 and the two main portions 311 are placed in a forming mold (not shown). The metal strip assembly 330 is received in the opening 310 and sandwiched between the two main portions 311. A gap (not shown) is defined between each main portion 311 and the metal strip assembly 330. A distance between each main portion 311 and the metal strip assembly 330 is substantially equal to the thickness of each adhering layer 35 along a direction from a metal strip 33 located at one side of adhering layer 35 to another adjacent metal strip 33 located at an opposite side of the adhering layer 35. Liquid molten plastic is injected into the mold filling the remaining gaps between each main portion 311 and the metal strip assembly 330. The plastic is solidified to connect the main portions 311 and the metal strip assembly 330 together and forms the insulating layer 36 in each gap after cooling.

In other embodiments, the plastics can also be formed on the inner surface of the base 31 and cover each metal strip 33, each adhering layer 35, each insulating layer 36, and entirely or partially cover an end portion of each main portion 311 connected to the insulating layer 36, thereby forming the combining layer 37 after cooling. The combining layer 37 can further enhance a bonding strength among the main portions 311, the metal strips 33, the adhering layers 35, and the insulating layers 36, respectively.

In addition, the insulating layers 36 can be also formed by the same means as forming the adhering layers 35. That is, the plastic films 351 are formed on two side surfaces of each metal strip 33 and the metal strips 33 and the main portions 311 are bonded together through hot pressing the plastic films 351.

A redundant portion of each metal strip 33 exposed from the outer surface of the base 31 can be removed by numerical control machines so the metal strips 33 and the base 31 can obtain a smooth appearance. Finally, the housing 30 can be polished or decorated.

The plurality of metal strips 33 and the plurality of adhering layers 35 are formed on the housing 30 corresponding to the antenna 50 to reduce interference from the housing 30 to the antenna 50. In addition, the base 31 can be coupled with the antenna 50 to serve as the extra antenna of the electronic device 100 to increase the radiation efficiency of the antenna 50. The metal strips 33 and the main portions 311 are aligned with each other. Each adhering layer 35 is positioned between two adjacent metal strips 33. Each insulating layer 36 is positioned between each main portion 311 and the adjacent metal strip 33. Thus, the metal strips 33 and the main portions 311 are connected to each other by the adhering layers 35 and the insulating layers 36. The combining layer 37 formed on the inner surface of the base 31 enhances the bonding strength among the main portion 311, the metal strips 33 the adhering layers 35, and the insulating layers 36 respectively.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A housing, comprising:
a base,
the base having a plurality of main portions separated by one or more openings formed therein;
a metal strip assembly positioned within the openings, the metal strip assembly formed by a series of metal strips fixed together by adhering layers; and
insulating layers being positioned between the metal strip assembly and the main portions.

2. The housing as claimed in claim 1, wherein the plurality of openings divide the base into at least two main portions, the at least two main portions are separated from each other or connected to each other through at least one portion of the base adjacent to the openings.

3. The housing as claimed in claim 1, wherein the thickness of each metal strip is about 0.1 mm to about 1.0 mm along a direction from an adjacent adhering layer located at one side of the metal strip to another adjacent adhering layer located at an opposite side of the metal strip.

4. The housing as claimed in claim 1, wherein each adhering layer has a thickness of about 20 μm to about 0.8 μm along a direction from a metal strip located at one sided of adhering layer to another adjacent metal strip located at an opposite side of the adhering layer.

5. The housing as claimed in claim 1, wherein each adhering layer is made of polycarbonate, polyamide, or polyethylene terephthalate.

6. The housing as claimed in claim 1, wherein each insulating layer has a thickness of about 20 μm to about 0.8 μm along a direction from a metal strip located at one sided of adhering layer to another adjacent metal strip located at an opposite side of the adhering layer.

7. The housing as claimed in claim 1, wherein each insulating layer is made of one or more resins selected from a group consisting of polyphenylene sulfide, polybutylene terephthalate, polyamide, polyethylene terephthalate, polytrimethylene terephthalate, polyetherimide, polyether ether ketone, poly(ethylene-co-1,4-cyclohexylenedimethylene terephthalate), and their modified materials.

8. The housing as claimed in claim 1, wherein the base comprises a receiving space and an internal surface facing the receiving space; a combining layer is attached to the internal surface, the combining layer covers the metal strips, the adhering layers, the insulating layers, and totally or partly covers an end of the main portion connected with the insulating layers.

9. The housing as claimed in claim 8, wherein the combining layer is made of one or more resins selected from a group consisting of polyphenylene sulfide, polybutylene terephthalate, polyamide, polyethylene terephthalate, polytrimethylene terephthalate, polyetherimide, polyether ether ketone, poly(ethylene-co-1,4-cyclohexylenedimethylene terephthalate), and their modified materials.

10. The housing as claimed in claim 1, wherein the base and the metal are metal selected from a group consisting of aluminum alloy, titanium alloy, magnesium alloy, and stainless steel.

11. A method of making a housing comprising:
providing a base defining a plurality of openings;
providing a plurality of metal strips, each side surface of each metal strip forming a plastic film;
overlapping the metal strips and heating the overlapped metal strips so that the plastic films are melted, and then solidified to form a plurality of adhering layers adhering the metal strips together as a metal strip assembly;
placing the metal strip assembly and the base in a forming mold with the metal assembly received in the openings, defining a gap between each side of the metal strip assembly and the base; and
injecting liquid molten plastics into the forming mold so that the plastics is filled into the gaps and connects the metal strip assembly and the base together to form the housing.

12. The method as claimed in claim 11, wherein the plurality of openings divide the base into at least two main portions, the at least two main portions are separated from each other or connected to each other through at least one portion of the base adjacent to the openings.

13. The method as claimed in claim 11, wherein the plastic films are made of polycarbonate, polyamide, or polyethylene terephthalate.

14. The method as claimed in claim 11, wherein the plastics filled into the gaps form a plurality of insulating layers.

15. The method as claimed in claim 11, wherein in the step of injecting liquid molten plastics into the forming mold, a combining layer is formed on an inner surface of the base covering the adhering layers and the metal strip assembly, thereby connecting the base, the metal strip assembly, and the adhering layers together.

16. The method as claimed in claim 11, further comprising removing a portion of each metal strip exposed from the outer surface of the base.

17. An electronic device, comprising:
a main body, a housing mounted on the main body, and an antenna assembled in the housing; and
the housing is as claimed in claim 1; and
the metal strip assembly is corresponding to the antenna, signals of the antenna passing through the metal strip assembly.

18. The electronic device as claimed in claim 17, wherein each insulating layer has a thickness of about 20 μm to about 0.8 μm along a direction from a metal strip located at one sided of adhering layer to another adjacent metal strip located at an opposite side of the adhering layer.

19. The electronic device as claimed in claim 17, wherein each insulating layer is made of one or more resins selected from a group consisting of polyphenylene sulfide, polybutylene terephthalate, polyamide, polyethylene terephthalate, polytrimethylene terephthalate, polyetherimide, polyether ether ketone, poly(ethylene-co-1,4-cyclohexylenedimethylene terephthalate), and their modified materials

20. The electronic device as claimed in claim 17, wherein the base comprises a receiving space and an internal surface facing the receiving space; a combining layer is attached to the internal surface, the combining layer covers the metal strips, the adhering layers, the insulating layers, and totally or partly covers an end of the main portion connected with the insulating layers.
